(19) United States
(12) Patent Application Publication
(10) Pub. No.: US 2005/0029660 A1
(43) Pub. Date: Feb. 10, 2005

(54) Adhesions of structures formed from materials of poor adhesion

(75) Inventors: Eike Ruttkowski, Munchen (DE); Franz Hofmann, Munchen (DE); Bjorn-Oliver Eversmann, Munchen (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/899,444

(22) Filed: Jul. 26, 2004

(30) Foreign Application Priority Data
Jul. 25, 2003 (DE) 103 34 124.2

(51) Int. Cl. B05D 5/12; H01L 21/4763; H01L 23/52

(52) U.S. Cl. 257/753; 427/58; 438/628

(57) ABSTRACT

Semiconductor device having a substrate, at least one adhesion promoter core, which is deposited on a part of the substrate, and a deposit, which completely surrounds the adhesion promoter core, of a material of poor adhesion which is different than the adhesion promoter material and is in direct contact with the substrate, as well as methods-for the production thereof.

### CROSS-REFERENCE TO RELATED APPLICATION

This application claims priority to German Patent Application No. 103 34 124.2-33 filed Jul. 25, 2003, and is incorporated herein by reference in its entirety.

### FIELD OF THE INVENTION

The present invention relates to an electronic device, in particular a semiconductor device, comprising a substrate, at least one adhesion promoter core, which is deposited on a part of the substrate, and a deposit, which completely surrounds the adhesion promoter core, of a material of poor adhesion which is different than the adhesion promoter material and is in direct contact with the substrate, and to methods for the production thereof.

### BACKGROUND OF THE INVENTION

The prior art has disclosed electronic devices which ensure the adhesion of a structure formed from a material of poor adhesion, such as for example silver or platinum, used in particular as interconnect material, to a substrate, such as Si or SiO₂, by the provision of an adhesion promoter layer which is applied over the entire contact surface between the structure formed from the material of poor adhesion and the substrate (cf. FIG. 1). However, a device of this type has the drawback that the material of poor adhesion is not in direct contact with the substrate, but rather is separated from it by the adhesion promoter, and the flanks of the adhesion promoter are uncovered and therefore, depending on the material selected for the adhesion promoter, may, for example, be susceptible to oxidation.

### SUMMARY OF THE INVENTION

In view of this background, it is an object of the present invention to provide an electronic device which is intended to allow both good adhesion of a material of poor adhesion to a substrate and direct contact between this material of poor adhesion and the substrate without an adhesion promoter having to be arranged over the entire contact surface between the structure formed from the material of poor adhesion and the substrate.

This object is achieved by the embodiments which are characterized in the claims.

In particular, the present invention provides an electronic device, comprising a substrate, at least one adhesion promoter core, which is deposited on a part of the substrate, and a layer or deposit, which completely surrounds the adhesion promoter core, of a material of poor adhesion which is different than the adhesion promoter material and is in direct contact with the substrate.

In the context of the present invention, an adhesion promoter core or an adhesion promoter structure (of any desired form) is to be understood as meaning a structure which is deposited on a substrate, for example a structure in the manometer range formed by sputtering or vapor deposition, which has a smaller dimension or size or feature size than the surrounding deposit of the material of poor adhesion. An adhesion promoter core in particular has the property of significantly improving the adhesion or bonding between a substrate, for example Si or SiO₂, and a material of poor or inadequate adhesion thereon, for example precious metals, which are used in particular as interconnect material.

In the context of the present invention, it has been established that if an adhesion promoter core with a smaller feature size than the material of poor adhesion deposited above it is provided, excellent adhesion can advantageously be achieved between the material that is different than the adhesion promoter material and the substrate.

Electronic arrangements usually comprise a multiplicity of individual devices according to the invention of this type. In this context, it is important for the adhesion promoter cores which are surrounded by the layer of the material of poor adhesion to be physically separated from one another, i.e., not to be in contact with one another, for example in physical or conductive contact. In general, the surrounded adhesion promoter cores are physically separated from one another in such a manner that the substrate is uncovered between the surrounded adhesion promoter cores. The spacing between the adhesion promoter cores on the substrate is not subject to any particular limitation but is usually in the micrometer or nanometer range. It is preferable for the spacing between the surrounded adhesion promoter cares in the lateral direction (based on the boundaries or edges of the structures) to be in a range from 20 nm to 200 nm.

According to one embodiment of the present invention, the adhesion promoter core is completely surrounded by the material of poor adhesion. Consequently, it is possible to achieve a very effective direct contact between the layer or cladding of the material of poor adhesion that is different than the adhesion promoter material and the substrate while at the same time ensuring improved adhesion.

Another embodiment of the present invention provides an electronic device, comprising a substrate, at least one adhesion promoter core, which is deposited on a part of the substrate, and has a layer or deposit arranged at its flanks or side faces, of a material of poor adhesion which is different than the adhesion promoter material and is in direct contact with the substrate, and a layer, formed from a reaction product of the adhesion promoter material on that surface or side of the adhesion promoter core which is on the opposite side to or remote from the substrate, so that the layer formed from a reaction product of the adhesion promoter material and the deposit of the material of poor adhesion completely surrounds or encircles or embeds the adhesion promoter core arranged on the substrate.

The reaction product of the adhesion promoter material may in principle be any reaction product obtainable from the adhesion promoter material and a compound which is reactive therewith. It is preferable for the reaction product of the adhesion promoter material to be an oxide of the adhesion promoter material which is formed in an oxygen-containing atmosphere.

The substrate which can be used in the present invention is not subject to any specific limitations. Therefore, examples of suitable substrates may include metals, semiconductors, oxide and nitride compounds, glass, polymers, etc. In the context of the present invention, it is preferable to use semiconductor substrates, with the substrate particularly preferably being selected from Si or SiO₂.

The shape of the substrate is not subject to any particular limitation. It is preferable for the substrate to be planar or flat. The thickness of the substrate is likewise not subject to any specific limitation and is usually dependent on the desired use.

The adhesion promoter material is a material which is suitable for providing good adhesion between the substrate and a material that is customarily used as interconnect material. A person skilled in this field will be familiar with suitable adhesion promoter materials and can select from them without great difficulty. Particularly preferred adhesion promoter materials include Ti, Cr, Zr or Hf or mixtures or alloys thereof.

The material of poor adhesion that surrounds the adhesion, promoter core is preferably a precious metal, such as Au, Ag, Pd or Pt or an alloy or mixtures thereof.

The thickness (layer thickness) of the adhesion promoter core may be in a range from 10 nm to 200 nm, with a thickness in a range from 30 nm to 60 nm being preferred and a thickness of approximately 50 am being particularly preferred.

The thickness of the layer or deposit of the material of poor adhesion that is different than the adhesion promoter material may, based on the distance from the substrate surface, be in a range from 10 nm to 1000 nm with a thickness in a range from 50 nm to 800 nm being preferred, and a thickness of from 100 nm to 500 nm being particularly preferred.

Depending on the lithography process which is employed, the feature size or lateral dimension of the adhesion promoter core may be in a range from 15 nm to 350 nm. The feature size of the adhesion promoter core which is surrounded by a layer or deposit of the material of poor adhesion that is different than the adhesion promoter material may be in a range from 20 nm to 300 nm.

The thickness of the layer of the reaction product of the adhesion promoter material may be in a range from 10 nm to 200 rim, with a thickness of from 10 nm to 50 nm being preferred.

Furthermore, the present invention provides a method for fabricating a device, as defined above, comprising the steps of:
(i) providing a substrate,
(ii) arranging at least one adhesion promoter core on the substrate, and
(iii) depositing the material of poor adhesion that is different than the adhesion promoter material onto the substrate over the adhesion promoter core, in such a manner that the adhesion promoter core is surrounded by a layer of the material of poor adhesion.

In one embodiment of the above method, steps (ii) and (iii,) can be carried out using different structure masks, with the mask feature size being selected to be smaller in step (ii) than in step (iii) (cf. FIG. 2).

In another embodiment of the above method, steps (ii) and (iii) can be carried out using the same structure masks, in which case after step (iii) further material of poor adhesion is deposited with the aid of a conformal deposition step, so that as a result a layer of material of poor adhesion, known as a spacer of material of poor adhesion, is also formed at the side faces or flank sides. Then, material of poor adhesion can be removed selectively, for example by anisotropic etching, such as reactive ion etching, in such a manner as to form a structure as illustrated in FIG. 3. In this context, the term conformal deposition is to be understood as meaning deposition in which the layer to be produced is formed at the same rate at vertical edges of the structure as at horizontal surfaces; cf. U. Hilleringmann, Silizium-Halbleitertechnologie, [Silicon semiconductor technology] Teubner-Verlag, 1996, Chapter 7.1.2.

The step of arranging or patterning an adhesion promoter core on the substrate in step (ii) may also be carried out by means of lift-off technology or by means of etching technology, for example by dry etching or by reactive ion etching. In the case of the lift-off technique, the starting point is a substrate with a customarily used resist film provided thereon, and then, for example, photolithography or electron beam lithography, etc., is carried out using a suitably selected mask. Then, resist material which has not cured is removed by being dissolved in a suitable solvent, and a vapor deposition step is carried out, in which the adhesion promoter material is applied in a desired thickness. Then, the webs of cured resist material and adhesion promoter material are removed by dissolution, so as to form a desired pattern of adhesion promoter cores on the substrate. The starting point in the case of the etching technique, for example, the reactive ion etching technique (RIE technique) is a substrate which has been evaporation-coated with adhesion promoter material and to which there has been applied a film of a customarily used resist. Then, certain regions of the resist film are cured, for example by electron beam lithography or photolithography using a suitably selected mask, and the uncured regions are removed using a suitable solvent. Holes are etched down to the depth of the substrate at the locations from which the resist film has been removed, the etchant preferably being selected in such a manner that is does not attack or scarcely attacks the substrate.

By means of the method described above, it is possible to produce adhesion, promoter cores in the micrometer or nanometer range on the substrate, for example, with a resolution in a range from 20 nm to 200 nm. Accordingly, the resolution of the desired adhesion promoter (core) structures on the substrate is limited only by the lithography limit.

The adhesion promoter material and/or the material of poor adhesion that is different than the adhesion promoter material may be applied to the substrate using any process which is customary in the specialist field. It is preferable for the adhesion promoter material and/or the material of poor adhesion that is different than the adhesion promoter material to be applied by sputtering techniques or atomic layer deposition processes (ALD processes) and, if there is no conformal deposition provided, for example by vapor deposition techniques.

The patterning of the material of poor adhesion that is different than the adhesion promoter material so as to form a layer or deposit which surrounds the adhesion promoter core in step (iii) may likewise be carried out by lift-off technology or by etching technology, as described above, using a suitable mask. If the lift-off technique is used, the starting point in step (iii) is a substrate with adhesion promoter cores which have already been patterned thereon, as described above under step (ii), then a customarily employed resist film is applied, and by way of example, photolithography or electron beam lithography, etc., is carried out using a suitably selected mask. Then, resist material which has not cured is removed by being dissolved in a suitable solvent, and the material of poor: adhesion that is different than the adhesion promoter material is applied in a desired thickness. Then the webs of cured resist material and the material of poor adhesion that is different than the adhesion promoter material are removed by dissolution, so that a desired structure, as shown in FIG. 2, is produced. If the etching technique is applied, for example, the reactive ion etching technique (RIE technique) the starting point in step (iii) is a substrate with adhesion promoter cores which have already been patterned thereon, as described above, and then a material of poor adhesion that is different than the adhesion promoter material is applied in a suitable thickness. Then, a film of a customarily used resist is applied, and the resist material is cured in the desired way, for example by electron beam lithography or photolithography, using a suitably selected mask, with predetermined regions of the resist film being cured. The uncured regions of the resist film, which substantially correspond to the regions between the adhesion promoter cores or the surrounded adhesion promoter cores are removed using a suitable solvent. Holes are etched, preferably down to the depth of the substrate, at the locations from which the resist film has been removed, these locations substantially corresponding to the regions between the adhesion promoter cores or the surrounded adhesion promoter cores, with the etchant preferably being selected in such a manner that it does not attack or scarcely attacks the substrate. A structure as shown in FIG. 2 can also be produced using the method described above.

According to a further embodiment, the present invention provides a method for fabricating a device, as defined above, comprising the steps of:
(i) providing a substrate,
(ii) arranging at least one adhesion promoter core on the substrate,
(iii) depositing the material of poor adhesion that is different than the adhesion promoter material onto the substrate over the adhesion promoter core, in such a manner that the adhesion promoter core is surrounded by a layer of the material of poor adhesion,
(iv) selectively removing the material of poor adhesion on that side of the adhesion promoter core which is remote from the substrate so that the adhesion promoter material is uncovered on the side remote from the substrate, and
(v) reacting the adhesion promoter material which was uncovered in step (iv) on the side remote from the substrate, in a reactive atmosphere, so as to form a layer of a reaction product of the adhesion promoter material.

With an embodiment of this type, it is customary first of all to deposit and pattern an adhesion promoter layer on the substrate such as Si or SiO₂. After the patterning step, a layer of material of poor adhesion, known as a spacer of material of poor adhesion, is formed at the side faces or flank sides with the aid of a conformal deposition step. The step of selective or regional removal of the material of poor adhesion which is different than the adhesion promoter material on that side of the adhesion promoter core which is remote from the substrate, with the adhesion promoter material being uncovered on the side remote from the substrate (step (iv)), can be carried out by etching (back) and/or anisotropic etching, such as reactive ion etching. In the case of etching (back), the uneven advance of the etching front by a suitable etchant forms a structure in which an adhesion promoter core remains on the substrate, and this adhesion promoter core has the material of poor adhesion that is different than the adhesion promoter material only at the flanks or on the side of the adhesion promoter core. By means of this selective etching step, it is possible to deliberately uncover that side of the adhesion promoter material which is remote from the substrate and to react it, for example in a reactive atmosphere, to form a layer of a reaction product of the adhesion promoter material (cf. FIG. 4). The reaction product of the adhesion promoter material may in principle be any reaction product obtainable from the adhesion promoter material and a compound which is reactive therewith. It is preferable for the reaction product of the adhesion promoter material to be an oxide of the adhesion promoter material which is formed in an oxygen-containing atmosphere, i.e., the adhesion promoter material is thermally oxidized.

The specific structure of the devices according to the invention, i.e., the cross section thereof, can be detected by means of SEM examination.

### BRIEF DESCRIPTION OF THE DRAWINGS

FIG. 1 shows a cross section of a device according to the prior art;

FIG. 2 shows a cross section of a device according to a first embodiment of the present invention;

FIG. 3 shows a cross section of a device according to a second embodiment of the present invention; and

FIG. 4 shows a cross section of a device according to a third embodiment of the present invention.

### DETAILED DESCRIPTION OF THE PREFERRED MODE OF THE INVENTION

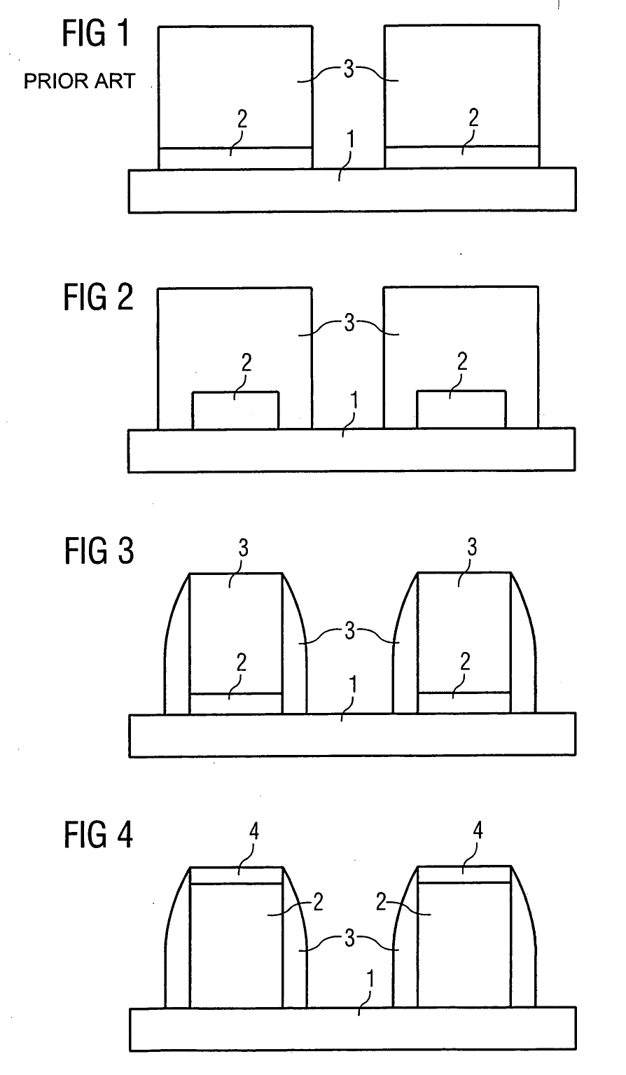

FIG. 1 shows a cross section through a device according to the prior art. This prior art device has a substrate 1, an adhesion promoter core 2 deposited thereon, and a layer or deposit 3 of a material of poor adhesion that is different than the adhesion promoter material. The deposit 3 is not in direct contact with the substrate 1. The flanks of the adhesion promoter core 2 are open.

FIG. 2 shows a cross section through a device according to a first embodiment of the present invention. This device has a substrate 1, an adhesion promoter core 2 deposited thereon, and a layer or deposit 3, which surrounds the adhesion promoter core 2, of a material of poor adhesion that is different than the adhesion promoter material, which layer or deposit is in direct contact with the substrate. To produce this device, a feature size of the adhesion promoter core is selected to be smaller than that of the material of poor adhesion.

FIG. 3 shows the cross section through a device according to a second embodiment of the present invention. This device has a substrate 1, an adhesion promoter core 2 deposited thereon and a layer or deposit 3, which surrounds the adhesion promoter core 2, of a material of poor adhesion that is different than the adhesion promoter material, which layer or deposit is in direct contact with the substrate. The same mask was used to pattern the adhesion promoter core and the layer of material of poor adhesion, so that the lithography limit can be utilized by using just one mask. After the patterning, a spacer of material of poor adhesion is produced by means of conformal deposition; cf. the diagrammatically indicated flank surfaces in FIG. 3.

FIG. 4 shows a cross section through a device according to a third embodiment of the present invention. This device has a substrate 1, an adhesion promoter core 2 which is deposited thereon and has a layer or deposit 3, which surrounds the adhesion promoter core at the flanks and is produced by means of conformal deposition, of a material of poor adhesion that is different than the adhesion promoter material, which layer or deposit is in direct contact with the substrate, and a layer 4 formed from a reaction product of the adhesion promoter material on that side of the adhesion promoter core which is remote from the substrate.

1. An electronic device, comprising:
a substrate;
at least one adhesion promoter core, which is deposited on a part of the substrate; and
a deposit, which completely surrounds the adhesion promoter core, of a material of poor adhesion which is different than a material of the adhesion promoter core and is in direct contact with the substrate.

2. The device as claimed in claim 1, wherein the adhesion promoter material is selected from a group consisting of Ti, Cr, Zr, Hf, a mixture thereof, and an alloy thereof.

3. The device as claimed in claim 1, wherein the material of poor adhesion that is different than the adhesion promoter material is selected from a group consisting of Au, Ag, Pt, Pd, a mixture thereof, and an alloy thereof.

4. The device as claimed in claim 1, wherein the substrate is Si or SiO₂.

5. An electronic device, comprising:
a substrate;
at least one adhesion promoter core, which is deposited on a part of the substrate;
a deposit arranged on side faces of the at least one promoter core, of a material of poor adhesion which is different than the adhesion promoter material and is in direct contact with the substrate; and
a layer, formed from a reaction product of the adhesion promoter material on that side of the adhesion promoter core which is remote from the substrate, so that the layer formed from a reaction product of a material of the adhesion promoter core and the deposit of the material of poor adhesion completely surrounds the adhesion promoter core arranged on the substrate.

6. The device as claimed in claim 5, wherein the adhesion promoter material is selected from a group consisting of Ti, Cr, Zr, Hf, a mixture thereof, and an alloy thereof.

7. The device as claimed in claim 5, wherein the material of poor adhesion that is different than the adhesion promoter material is selected from the group consisting of Au, Ag, Pt, Pd, a mixture thereof, and an alloy thereof.

8. The device as claimed in claim 5, wherein the reaction product of the adhesion promoter material is an oxide of the adhesion promoter material.

9. A method for fabricating the electronic device as claimed in claim 1, comprising the steps of:
(i) providing a substrate;
(ii) arranging at least one adhesion promoter core on the substrate; and
(iii) depositing a material of poor adhesion that is different than a material of the adhesion promoter core onto the substrate over the adhesion promoter core, in such a manner that the adhesion promoter core is surrounded by a layer of the material of poor adhesion.

10. The method as claimed in claim 9, wherein steps (ii) and (iii) are carried out using different structure masks, with the mask feature size being selected to be smaller in step (ii) than in step (iii).

11. The method as claimed in claim 9, wherein steps (ii) and (iii) are carried out using the same structure masks, and step (iii) is then also followed by conformal deposition of material of poor adhesion.

12. A method for fabricating the electronic device as claimed in claim 5, comprising the steps of:
(i) providing a substrate;
(ii) arranging at least one adhesion promoter core on the substrate;
(iii) depositing a material of poor adhesion that is different than a material of the adhesion promoter core onto the substrate over the adhesion promoter core, in such a manner that the adhesion promoter core is surrounded by a layer of the material of poor adhesion;
(iv) selectively removing the material of poor adhesion on that side of the adhesion promoter core which is remote from the substrate so that the adhesion promoter material is uncovered on the side remote from the substrate; and
(v) reacting the adhesion promoter material which was uncovered in step (iv) on the side remote from the substrate, in a reactive atmosphere, so as to form a layer of a reaction product of the adhesion promoter material.

13. The method as claimed in claim 12, wherein in step (v) reaction of the adhesion promoter material is carried out in an oxygen-containing atmosphere.

14. The method as claimed in claim 9, wherein in the step of arranging the adhesion promoter material on the substrate and/or of depositing the material of poor adhesion is carried out by sputtering technology.

15. The method as claimed in claim 9, wherein the patterning of the adhesion promoter core and/or of the material of poor adhesion is carried out by lift-off technology or etching.

16. An electronic arrangement, comprising a multiplicity of the devices as claimed in claim 1, wherein spacing between the surrounded adhesion promoter cores in the lateral direction is in the range from 20 nm to 200 nm.

17. An electronic arrangement, comprising a multiplicity of the devices as claimed in claim 5, wherein spacing between the surrounded adhesion promoter cores in the lateral direction is in the range from 20 nm to 200 nm.

18. An electronic arrangement produced using the method as claimed in claim 9, wherein spacing between the surrounded adhesion promoter cores in the lateral direction is in the range from 20 nm to 200 nm.

19. An electronic arrangement produced using the method as claimed in claim 12, wherein spacing between the surrounded adhesion promoter cores in the lateral direction is in the range from 20 nm to 200 nm.
